(19) United States
(12) Patent Application Publication
(10) Pub. No.: US 2024/0403718 A1
(43) Pub. Date: Dec. 5, 2024

(54) LEARNING DEVICE, ANOMALY INDICATION DETECTION DEVICE, ANOMALY INDICATION DETECTION SYSTEM, LEARNING METHOD, AND STORAGE MEDIUM

(71) Applicant: Mitsubishi Electric Corporation, Chiyoda-ku, Tokyo (JP)

(72) Inventor: Tomo SAKO, Tokyo (JP)

(73) Assignee: Mitsubishi Electric Corporation, Chiyoda-ku, Tokyo (JP)

(21) Appl. No.: 18/701,559

(22) PCT Filed: Nov. 30, 2021
(86) PCT No.: PCT/JP2021/043847

§ 371 Date: Apr. 15, 2024

(51) Int. Cl. G06N 20/00; G01R 31/08

(52) U.S. Cl. CPC G06N 20/00; G01R 31/08

(57) ABSTRACT

A learning device generates learned data to be used for anomaly indication detection. The learning device includes a preprocessing unit that subtracts, from a value at each of points in one cycle of normal data, an average of values at corresponding points in normal data from one to N cycles ago in computing difference values with respect to the preceding N cycles, the one cycle corresponding to a specified time length, N being an integer greater than or equal to 2, the normal data being data from a normal state; and a first waveform analysis unit that generates, through waveform similarity analysis using the difference values with respect to the preceding N cycles, normal waveforms and a normality determination threshold to be used in determining whether or not there is normality as the learned data.

### FIELD

The present disclosure relates to a learning device that performs machine learning for anomaly indication detection and also relates to an anomaly indication detection device, an anomaly indication detection system, a learning method, and a program.

### BACKGROUND

For various important equipment, including equipment in a power system and equipment in various plants, malfunctions have a significant effect. Therefore, detecting anomaly indications before the malfunctions occur is desired. For example, a ground fault and others that occur in a power distribution system can be associated with some precursor phenomena, and techniques for capturing these precursor phenomena have been proposed.

For example, Patent Literature 1 below discloses a technique for inferring an insulation deterioration state through supervised learning using a neural network model that uses at least one of a frequency spectrum of zero-phase voltage or a frequency spectrum of zero-phase current in a power distribution system.

### CITATION LIST

### Patent Literature

Patent Literature 1: Japanese Patent Application Laid-open No. H5-122829

### SUMMARY OF INVENTION

### Problem to be Solved by the Invention

During an instantaneous ground fault, at least one of the zero-phase voltage or the zero-phase current includes many sub-harmonic components in addition to a power supply frequency and integral multiple frequencies, and the frequency spectrum of the zero-phase voltage shows a tendency for magnitude to increase with decreasing frequency below the power supply frequency. Based on these premises, the technique described in Patent Literature 1 uses signals that manifest such characteristics as training signals. However, forerunners of malfunctions conceivably include not only those with such known waveform characteristics but also various waveforms depending on factors. Malfunctions can occur particularly in distribution lines installed in mountainous areas under the influence of fallen trees, bird's nests, and others. Forerunners of the malfunctions due to these phenomena do not necessarily have the frequency spectrum characteristics described in Patent Literature 1. Therefore, for the technique described in Patent Literature 1, accuracy of anomaly indication detection may not be satisfactory.

The present disclosure has been made in view of the above, and an object of the present disclosure is to obtain a learning device that allows for improved accuracy of anomaly indication detection.

### Means to Solve the Problem

In order to solve the above-described problems and achieve the object, a learning device according to the present disclosure generates learned data to be used for anomaly indication detection. The learning device includes a preprocessing unit to subtract, from a value at each of points in one cycle of normal data, an average of values at corresponding points in the normal data from one to N cycles ago in computing difference values with respect to the preceding N cycles, the one cycle corresponding to a specified time length, N being an integer greater than or equal to 2, the normal data being data from a normal state. The learning device further includes a first waveform analysis unit to generate, through waveform similarity analysis using the difference values with respect to the preceding N cycles, normal waveforms and a normality determination threshold to be used in determining whether or not there is normality as the learned data.

### Effect of the Invention

The learning device according to the present disclosure has an effect of enabling improved accuracy of anomaly indication detection.

### BRIEF DESCRIPTION OF DRAWINGS

FIG. 1 is a diagram illustrating a configuration example of an anomaly indication detection system according to a first embodiment.

FIG. 2 is a diagram of an example illustrating how the anomaly indication detection system according to the first embodiment is set up in a power distribution system.

FIG. 3 is a flowchart illustrating an example of a procedure during learning by a learning device according to the first embodiment.

FIG. 4 is a flowchart illustrating an example of a procedure during inference by an anomaly indication detection device according to the first embodiment.

FIG. 5 is a diagram used for describing preprocessing according to the first embodiment.

FIG. 6 is a diagram schematically illustrating an example of an effect of the preprocessing according to the first embodiment.

FIG. 7 is a diagram illustrating a configuration example of a computer system that implements the learning device according to the first embodiment.

FIG. 8 is a diagram illustrating a configuration example of an anomaly indication detection system according to a second embodiment.

FIG. 9 is a flowchart illustrating an example of a procedure for learning waveforms with anomaly indications through waveform similarity analysis according to the second embodiment.

FIG. 10 is a flowchart illustrating an example of a procedure during inference by an anomaly indication detection device according to the second embodiment.

FIG. 11 is a diagram illustrating a configuration example of an anomaly indication detection system according to a third embodiment.

FIG. 12 is a flowchart illustrating an example of a procedure for learning using root-mean-square values according to the third embodiment.

FIG. 13 is a flowchart illustrating an example of a procedure during inference by an anomaly indication detection device according to the third embodiment.

FIG. 14 is a diagram illustrating a configuration example of an anomaly indication detection system according to a fourth embodiment.

FIG. 15 is a flowchart illustrating an example of a procedure during inference by an anomaly indication detection device according to the fourth embodiment.

FIG. 16 is a diagram illustrating a configuration example of an anomaly indication detection system according to a fifth embodiment.

FIG. 17 is a flowchart illustrating an example of a procedure for waveform similarity analysis where waveforms with anomaly indications are learned according to the fifth embodiment.

### DESCRIPTION OF EMBODIMENTS

With reference to the drawings, a detailed description is hereinafter provided of learning devices, anomaly indication detection devices, anomaly indication detection systems, learning methods, and programs according to embodiments.

### First Embodiment

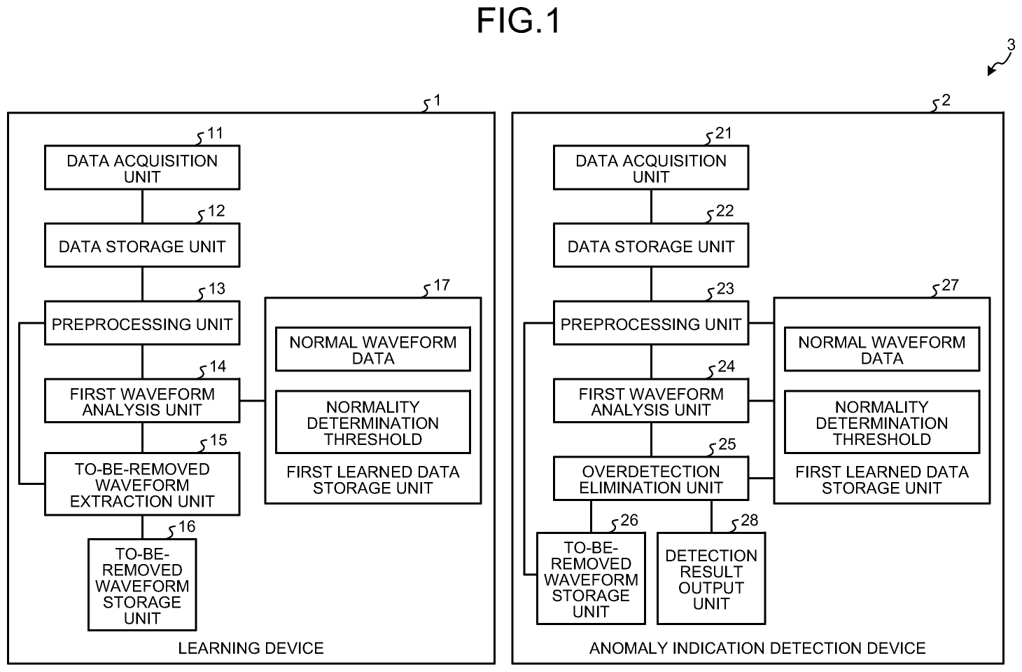

FIG. 1 is a diagram illustrating a configuration example of an anomaly indication detection system according to a first embodiment. The anomaly indication detection system 3 according to the present embodiment includes a learning device 1 and an anomaly indication detection device 2. The learning device 1 generates learned data to be used for anomaly indication detection, and the anomaly indication detection device 2 uses the learned data generated by the learning device 1 to detect indications of anomaly. For example, the learning device 1 performs learning for the anomaly detection through waveform analysis of time-series data obtained by a sensor or another device. Waveform analyses of the present embodiment are examples of machine learning and are also called waveform similarity analyses. The waveform analysis during the learning includes accumulating standard waveforms as reference waveforms and determining a threshold based on outlier scores indicating similarities to the reference waveforms. The waveform analysis of the present embodiment during the detection of indications of anomaly, namely during inference of whether or not the anomaly indications are present includes using time-series data as a detection target and the reference waveforms to compute outlier scores of each of waveforms included in the time-series data (detection target) with respect to the reference waveforms and detecting the anomaly indications on the basis of results of comparison between outlier scores and the threshold determined by the learning.

As illustrated in FIG. 1, the learning device 1 includes a data acquisition unit 11, a data storage unit 12, a preprocessing unit 13, a first waveform analysis unit 14, a to-be-removed waveform extraction unit 15, a to-be-removed waveform storage unit 16, and a first learned data storage unit 17.

The data acquisition unit 11 obtains and stores in the data storage unit 12 time-series data from a normal period. For example, the data acquisition unit 11 obtains measured data from a sensor or another device that obtains time-series data. The preprocessing unit 13 performs, on the time-series data stored in the data storage unit 12, preprocessing including smoothing, segmentation into window sizes (each corresponding to one unit interval), and differencing with respect to preceding N cycles (where N is an integer greater than or equal to 2) and outputs the preprocessed data to the first waveform analysis unit 14. Because of having been segmented according to window size, the preprocessed data is output to the first waveform analysis unit 14 for each unit interval. Data within one unit interval is also referred to as unit interval data below. Furthermore, the preprocessing unit 13 outputs unit interval data yet to undergo the differencing with respect to preceding N cycles to the to-be-removed waveform extraction unit 15.

The first waveform analysis unit 14 learns normal waveforms through the waveform similarity analysis. Specifically, the first waveform analysis unit 14 computes a distance between preprocessed unit interval data and preprocessed unit interval data as an outlier score, uses computed outlier scores to determine a normality determination threshold to be used for determining whether or not there is normality, and stores the determined normality determination threshold in the first learned data storage unit 17. While the distance between unit interval data and unit interval data that is to be used may be any distance, such as dynamic time warping (DTW) distance, Mahalanobis distance, or Euclidean distance, the distance between unit interval data and unit interval data that is given here as an example is a cumulative value obtained for one unit interval data by adding distances at sampling points between unit interval data and unit interval data. The normality determination threshold is determined on the basis of, for example, a standard deviation of the outlier scores. For example, when the standard deviation of the outlier scores is σ, the first waveform analysis unit 14 sets the normality determination threshold to 3σ. Furthermore, the first waveform analysis unit 14 selects unit interval data to be stored as normal waveform data from among the data of the unit intervals and stores the selected unit interval data as the normal waveform data in the first learned data storage unit 17. Furthermore, the first waveform analysis unit 14 outputs to the to-be-removed waveform extraction unit 15 identification information identifying unit interval data determined to be normal data, but an infrequent waveform. The normal waveforms and the normality determination threshold that are stored in the first learned data storage unit 17 are the learned data to be used for the anomaly indication detection.

The to-be-removed waveform extraction unit 15 categorizes, among the data of the unit intervals received from the preprocessing unit 13, data of those unit intervals each corresponding to identification information received from the first waveform analysis unit 14, that is to say, the data of the unit intervals that have been determined to be the infrequent waveforms into plural waveform types and determines a condition of normality determination for each of the waveform types. The waveform condition of the normality determination is determined on the basis of, for example, an average of values at sample points within the unit interval data, a standard deviation, a maximum value, a minimum value, or another value. The to-be-removed waveform extraction unit 15 stores the corresponding waveforms and the waveform conditions by type in the to-be-removed waveform storage unit 16. The operation performed by the to-be-removed waveform extraction unit 15 is the operation performed for the purpose of preventing overdetection where a waveform, although normal, is determined to have an indication of anomaly by having a great outlier score as a result of, for example, some event not problematic. As described later, the information stored in the to-be-removed waveform storage unit 16 is used in an operation that is performed within the anomaly indication detection device 2 to prevent the overdetection. The elimination of overdetection that uses the waveform type-specific waveform condition determined by the to-be-removed waveform extraction unit 15 is also referred to as type-specific filtering.

The anomaly indication detection device 2 includes a data acquisition unit 21, a data storage unit 22, a preprocessing unit 23, a first waveform analysis unit 24, an overdetection elimination unit 25, a to-be-removed waveform storage unit 26, a first learned data storage unit 27, and a detection result output unit 28. The to-be-removed waveform storage unit 26 stores the same information as the above-mentioned to-be-removed waveform storage unit 16, and the first learned data storage unit 27 stores the same information as the above-mentioned first learned data storage unit 17.

The data acquisition unit 21 obtains and stores in the data storage unit 22 detection target data that is time-series data as an anomaly indication detection target. The preprocessing unit 23 performs the same preprocessing as the preprocessing unit 13 on the detection target data stored in the data storage unit 22 and outputs the preprocessed data to the first waveform analysis unit 24. Furthermore, the preprocessing unit 23 outputs unit interval data yet to undergo the differencing with respect to preceding N cycles to the overdetection elimination unit 25.

The first waveform analysis unit 24 uses preprocessed unit interval data and the learned data to determine whether or not there is an indication of anomaly through the waveform similarity analysis. Specifically, the first waveform analysis unit 24 determines whether or not the anomaly indication is present in the preprocessed unit interval data by comparing a distance between the preprocessed unit interval data and the data of each of the normal waveforms stored in the first learned data storage unit 27 with the normality determination threshold stored in the first learned data storage unit 27 and outputs a determination result to the overdetection elimination unit 25. For example, the first waveform analysis unit 24 determines that the anomaly indication is present when a minimum outlier score among computed outlier scores is beyond the normality determination threshold. When determining that the anomaly indication is present, the first waveform analysis unit 24 also outputs the corresponding unit interval data to the overdetection elimination unit 25.

When the determination result received from the first waveform analysis unit 24 is a determination result indicating that the anomaly indication is present, the overdetection elimination unit 25 identifies the waveform type of the unit interval data in question by comparing the unit interval data received from the preprocessing unit 23 with the type-specific waveforms stored in the to-be-removed waveform storage unit 26 and uses the normality determination condition corresponding to the identified type among the normality determination conditions stored in the to-be-removed waveform storage unit 26 to determine whether or not the unit interval data in question is normal. When the determination result received from the first waveform analysis unit 24 indicates that the anomaly indication is present and when the unit interval data in question is determined to be normal on the basis of the normality determination condition, the overdetection elimination unit 25 determines that no anomaly indication is present in the unit interval data in question and outputs a determination result to the detection result output unit 28. When the determination result received from the first waveform analysis unit 24 indicates that the anomaly indication is present and when the unit interval data in question is determined to be not normal on the basis of the normality determination condition, the overdetection elimination unit 25 determines that the anomaly indication is present in the unit interval data in question and outputs a determination result to the detection result output unit 28.

When the determination result received from the first waveform analysis unit 24 is a determination result indicating that there is no anomaly indication, the overdetection elimination unit 25 outputs this determination result to the detection result output unit 28.

When the first waveform analysis unit 24 determines that the anomaly indication is present, its determination result is provided as a notification for the detection result output unit 28 via the overdetection elimination unit 25 in the above-described example; however, this is not limiting. When the first waveform analysis unit 24 determines that the anomaly indication is present, the first waveform analysis unit 24 may provide its determination result as a direct notification for the detection result output unit 28. Even the determination result indicating that there is no anomaly indication is output to the detection result output unit 28 in the above-described example; however, this is not limiting. The determination result indicating that there is no anomaly indication does not have to be output to the detection result output unit 28. In other words, determination results may be output to the detection result output unit 28 only when anomaly indications are detected.

While the learning device 1 and the anomaly indication detection device 2 are separately provided in the example illustrated in FIG. 1, the learning device 1 and the anomaly indication detection device 2 may be integrated. In that case, the above-mentioned to-be-removed waveform storage unit 26 may be omitted for the to-be-removed waveform storage unit 16 to be used as the to-be-removed waveform storage unit 26, the above-mentioned first learned data storage unit 27 may be omitted for the first learned data storage unit 17 to be used as the first learned data storage unit 27, and the above-mentioned data storage unit 22 may be omitted for the data storage unit 12 to be used as the data storage unit 22. In addition, the data acquisition unit 21, the preprocessing unit 23, and the first waveform analysis unit 24 do not have to be provided when the data acquisition unit 11, the preprocessing unit 13, and the first waveform analysis unit 14 also have the functions of the data acquisition unit 21, the preprocessing unit 23, and the first waveform analysis unit 24. The learning device 1 and the anomaly indication detection device 2 have many common operations and can, therefore, share these common operations when integrated.

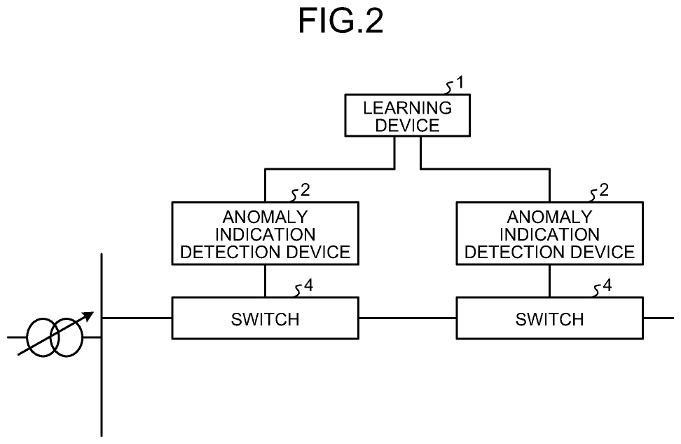

The anomaly indication detection system 3 according to the present embodiment can be applied to detect, for example, anomaly indications in a power distribution system. FIG. 2 is a diagram of an example illustrating how the anomaly indication detection system 3 according to the present embodiment is set up in the power distribution system. In the example illustrated in FIG. 2, each of the anomaly indication detection devices 2 is a device called a slave station that controls a switch 4 connecting sections in the power distribution system. Alternatively, each anomaly indication detection device 2 may be a device connected to a slave station controlling the switch 4.

In recent years, a wiring control system for automatically and remotely controlling the switches 4 in the power distribution system has been increasingly introduced. In such a system, the slave stations, which control the switches 4, communicate with a master station provided at a remote location. Each of the slave stations can monitor the power distribution system by taking measurements of current and voltage of the power distribution system and can control the switch 4 according to an instruction from the master station. As described above, each slave station measures the current and the voltage of the power distribution system. By being used as the slave station or connected to the slave station, each anomaly indication detection device 2 can detect anomaly indications in the power distribution system, using the measured current and voltage. The slave station is installed, for example, on a utility pole together with a transformer.

In the example illustrated in FIG. 2, the learning device 1 is the master station or is connected to the master station. Therefore, after performing learning, the learning device 1 can transmit data of the first learned data storage unit 17 and data of the to-be-removed waveform storage unit 16 to the anomaly indication detection device 2. It is to be noted that this method of reflecting the data of the first learned data storage unit 17 and the data of the to-be-removed waveform storage unit 16 in the anomaly indication detection device 2 is not a limiting example. These data may be transmitted from the learning device 1 to the anomaly indication detection device 2 by means of another communication network or may be obtained by the anomaly indication detection device 2 through a recording medium or the like.

In the power distribution system, anomalies can occur in distribution lines or other equipment of the power distribution system under the influence of fallen trees, contact with trees, birds, snakes, and others, particularly in mountainous areas. In the meantime, constantly monitoring the condition of the power distribution system in the mountainous areas is difficult for workers. Therefore, remotely monitoring the condition of the power distribution system and detecting anomaly indications are desirable. In the example illustrated in FIG. 2, the anomaly indication detection devices 2 can perform anomaly indication detection respectively at locations in the power distribution system. Therefore, when an anomaly indication is detected, a worker is enabled to take action before an anomaly occurs by performing on-site confirmation.

While a description provided below is of the example where anomaly indications in the power distribution system are detected, the anomaly indication detection system 3 according to the present embodiment is not limited to this example and can detect anomaly indications in time-series data obtained by sensors of other equipment in a power system, equipment in various plants, and other electrical equipment. Time-series data as an anomaly indication detection target may be any kind of data.

As described above, each slave station measures the current and the voltage. In the example described below, anomaly indication detection is performed, using measured instantaneous value data of at least one of zero-phase current or zero-phase voltage as time-series data. In other words, anomaly indication detection using measured data of either the zero-phase current or the zero-phase voltage may be performed, or anomaly indication detection using measured data of the zero-phase current and anomaly indication detection using measured data of the zero-phase voltage may both be performed. In the case of both, a determination is made that an anomaly indication has been detected when the anomaly indication is detected in either anomaly indication detection. The measured data of the zero-phase current and the measured data of the zero-phase voltage are assumed to be obtained as instantaneous values. In other words, the sensor that obtains time-series data in this example measures the at least one of the zero-phase current or the zero-phase voltage. For example, the measured data is obtained, with a sampling period sufficiently shorter than a power supply cycle of the power distribution system. Since the operations are the same for the case of using the zero-phase current and the case of using the zero-phase voltage, no distinction is made between the zero-phase current and the zero-phase voltage when measured instantaneous value data is described below.

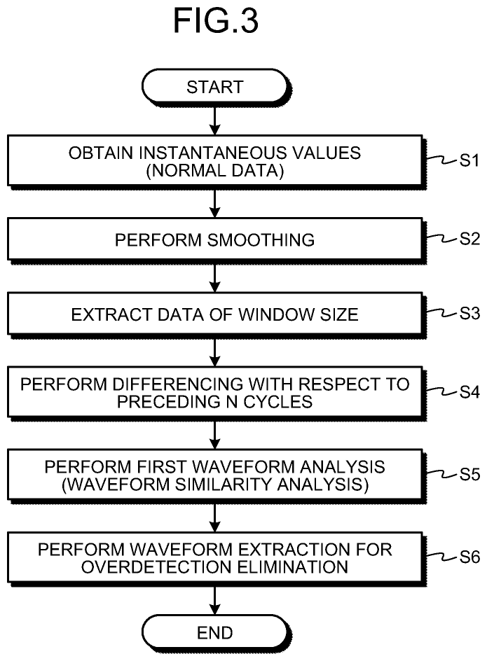

FIG. 3 is a flowchart illustrating an example of a procedure during learning by the learning device 1 according to the present embodiment. The learning device 1 obtains instantaneous values (normal data) (step S1). Specifically, the data acquisition unit 11 obtains the measured instantaneous value data of a normal period as time-series data and stores the obtained measured data in the data storage unit 12. The data acquisition unit 11 may obtain measured instantaneous value data of a period known to be normal from another device (not illustrated) that stores data previously obtained by a sensor. The data acquisition unit 11 may obtain measured instantaneous value data obtained by an experiment. As long as measured instantaneous value data is from a period known to be normal, the data acquisition unit 11 may obtain the measured instantaneous value data from the sensor.

Next, the learning device 1 performs the smoothing (step S2). Specifically, the preprocessing unit 13 performs the smoothing on the measured data stored in the data storage unit 12, using a first-order lag filter as an example. While a filter coefficient of the first-order lag filter may be set to any value, the preprocessing unit 13 performs, for example, the smoothing using the first-order lag filter, with a ratio of a preceding sampling point to a current sampling point set to 3:1 (75%:25%).

Next, the learning device 1 performs the data extraction (step S3). Specifically, the preprocessing unit 13 extracts data of a window size from the measured data stored in the data storage unit 12. More specifically, the preprocessing unit 13 generates unit interval data by segmenting the smoothed measured data by window size. The window size may be set in any way. In this example, the window size corresponds to one power supply cycle. The window size is not limited to this and may be set, for example, to two power supply cycles or another value.

Next, the learning device 1 performs the differencing with respect to preceding N cycles (step S4). Specifically, the preprocessing unit 13 performs the differencing with respect to preceding N cycles for data of each unit interval, that is to say, data of each window size. The differencing with respect to preceding N cycles is an operation of subtracting, from a value at each of points in one cycle of normal data (data from a normal state), an average of values at corresponding points in normal data from one to N cycles ago to compute difference values with respect to the preceding N cycles, where the one cycle corresponds to a specified time length. More specifically, the differencing with respect to preceding N cycles is the operation of subtracting, from the value at each point in the current unit interval data, the average of the values at the corresponding points from the one to N cycles ago. In other words, when the unit interval data to undergo the differencing with respect to preceding N cycles is the kth unit interval data and when an ith point within the kth unit interval data is P_{k,i}, Q_{k,i} as a result of the differencing with respect to the preceding N cycles can be expressed by Formula (1) below.

$${Q}_{k , i} = {P}_{k , i} - ( {P}_{k - 1 , i} + {P}_{k - 2 , i} + … + {P}_{k - N , i} ) / N \qquad ( 1 )$$

Next, the learning device 1 performs first waveform analysis (the waveform similarity analysis) (step S5). Specifically, the first waveform analysis unit 14 computes a distance between preprocessed unit interval data and preprocessed unit interval data to compute an outlier score and determines a standard deviation σ of computed outlier scores. The first waveform analysis unit 14 then sets the normality determination threshold to 3σ and selects data to be stored as data determined to be normal from among the data of the unit intervals. While the normality determination threshold is 3σ here, the normality determination threshold is not limited to this value and may be determined, for example, on the basis of a result of a prior assessment. The first waveform analysis unit 14 stores the selected data determined to be normal and the normality determination threshold in the first learned data storage unit 17. Furthermore, the first waveform analysis unit 14 notifies the to-be-removed waveform extraction unit 15 of identification information identifying unit interval data determined to be an infrequent normal waveform.

Next, the learning device 1 performs waveform extraction for overdetection elimination (step S6). Specifically, the to-be-removed waveform extraction unit 15 categorizes the data of the unit intervals each corresponding to identification information that the first waveform analysis unit 14 has notified of into plural waveform types and determines a condition of normality determination, that is to say, the normality determination condition, for each of the waveform types. The to-be-removed waveform extraction unit 15 then stores the data of the corresponding unit intervals and the normality determination conditions in the to-be-removed waveform storage unit 16. The above operation completes the learning. Once the learning is completed, relearning may be performed, using newly obtained measured data. In cases where the relearning is performed, learned data, namely information stored in the first learned data storage unit 17 and information stored in the to-be-removed waveform storage unit 16, are reflected in the anomaly indication detection device 2. Specifically, the reflection of the information in the anomaly indication detection device 2 is done, for example, by transmission from the learning device 1 to the anomaly indication detection device 2.

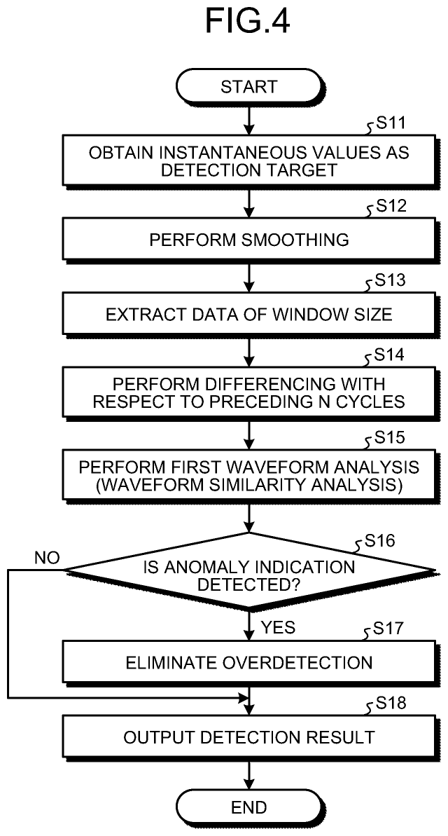

FIG. 4 is a flowchart illustrating an example of a procedure during inference by the anomaly indication detection device 2 according to the present embodiment. The anomaly indication detection device 2 obtains instantaneous values as a detection target (step S11). Specifically, the data acquisition unit 21 obtains measured instantaneous value data as an inference target or the anomaly indication detection target.

Next, the anomaly indication detection device 2 performs the preprocessing as in steps S2 to S4 on the instantaneous values as the detection target (steps S12 to S14). After step S14, the anomaly indication detection device 2 performs first waveform analysis (the waveform similarity analysis) (step S15). Specifically, the first waveform analysis unit 24 determines whether or not an anomaly indication is present in preprocessed unit interval data by comparing a distance between the preprocessed unit interval data and the data of each of the normal waveforms stored in the first learned data storage unit 27 with the normality determination threshold stored in the first learned data storage unit 27 and outputs a determination result to the overdetection elimination unit 25.

If the anomaly indication is detected as a result of the first waveform analysis (Yes at step S16), the anomaly indication detection device 2 eliminates the overdetection (step S17). Specifically, if the determination result received from the first waveform analysis unit 24 is a determination result indicating that the anomaly indication is present, the overdetection elimination unit 25 identifies the waveform type of the unit interval data in question by comparing the unit interval data received from the preprocessing unit 23 with the type-specific waveforms stored in the to-be-removed waveform storage unit 26, uses the normality determination condition corresponding to the identified type among the normality determination conditions stored in the to-be-removed waveform storage unit 26 to determine whether or not the unit interval data in question is normal, and outputs a determination result to the detection result output unit 28.

Next, the anomaly indication detection device 2 outputs a detection result (step S18). Specifically, the detection result output unit 28 outputs the determination result received from the overdetection elimination unit 25 as the detection result. Since the anomaly indication detection device 2 is the slave station or is connected to the slave station here, the detection result output unit 28 may output the detection result, for example, by transmitting the detection result to the learning device 1 or the master station different from the learning device 1. In cases where the anomaly indication detection device 2 includes a display unit, the detection result output unit 28 may be implemented by the display unit and provide the detection result output by displaying the detection result. Upon receiving the detection result from the anomaly indication detection device 2, the learning device 1 or the master station different from the learning device 1 displays the detection result on a display unit not illustrated in FIG. 1.

If no anomaly indication is detected (No at step S16), the anomaly indication detection device 2 proceeds to step S18 without performing the overdetection elimination in the process. As described above, the detection result may be output even when no anomaly indication is detected, that is to say, in the case of normality. Alternatively, the detection result does not have to be output when no anomaly indication is detected, but when the anomaly indication is detected.

While the overdetection elimination is performed in the above-described example, the overdetection elimination does not have to be performed. In that case, the to-be-removed waveform extraction unit 15, the to-be-removed waveform storage unit 16, the overdetection elimination unit 25, and the to-be-removed waveform storage unit 26 do not have to be provided. The data stored in the data storage unit 22 may be deleted, for example, after the elapse of a certain period or in chronological order when a certain amount is reached.

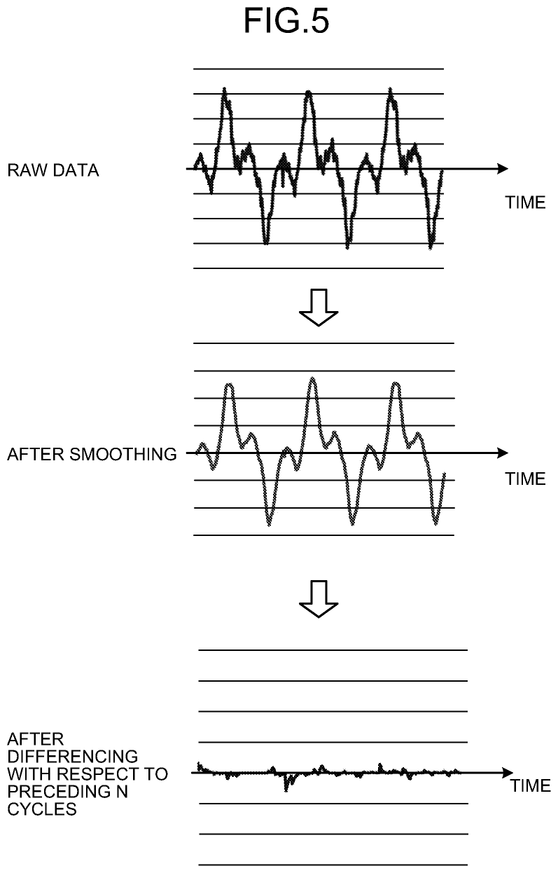

Next, a description is provided of an effect of the present embodiment. In the present embodiment, the preprocessing unit 13 performs the smoothing and the differencing with respect to preceding N cycles. FIG. 5 is a diagram used for describing the preprocessing according to the present embodiment. As illustrated in FIG. 5, raw data that is measured instantaneous value data includes various noises and thus takes on waveforms with many higher frequency components. For this reason, if the data undergoes the first waveform analysis, which is the waveform similarity analysis, as is, an error is greater, easily causing false anomaly indication detections. In the present embodiment, the smoothing is performed, enabling waveforms with reduced influence from the noises to be obtained as illustrated in a middle section of FIG. 5 and allowing for improved accuracy of anomaly indication detection. Furthermore, as illustrated in a bottom section of FIG. 5, performing the differencing with respect to preceding N cycles removes a component significantly changing in a power supply cycle-dependent manner, enabling easy detection of any substantial changes compared to when the raw data is used.

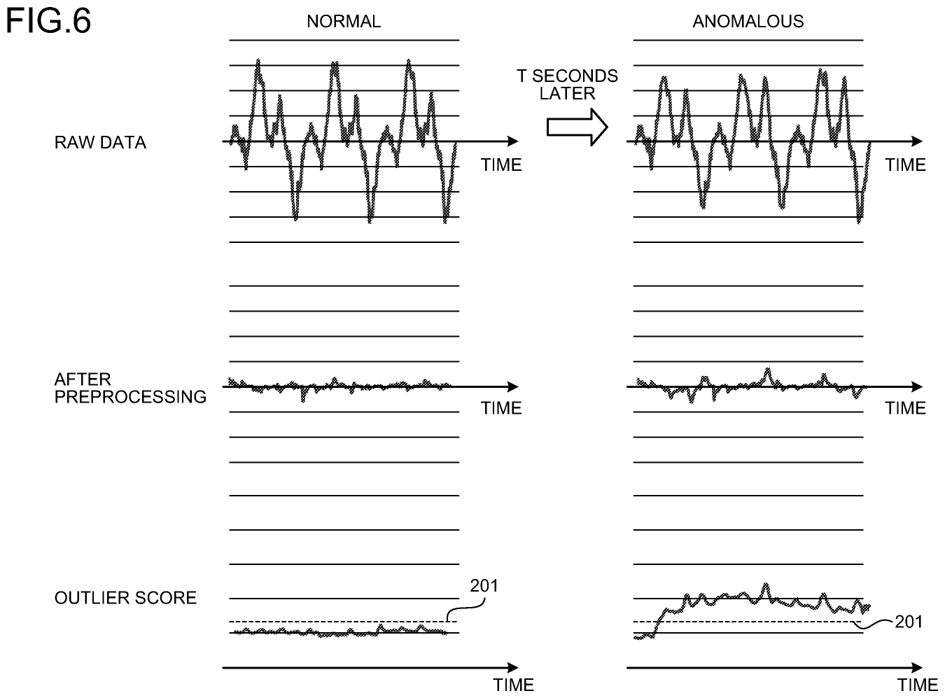

FIG. 6 is a diagram schematically illustrating an example of an effect of the preprocessing according to the present embodiment. FIG. 6 schematically illustrates results that are obtained when raw data corresponding to normal measured data as a detection target is input to the anomaly indication detection device 2 of the present embodiment and results that are obtained when raw data corresponding to measured data with appearing anomaly indications as a detection target is input to the anomaly indication detection device 2. The raw data corresponding to the normal measured data, the data that has undergone the preprocessing (the smoothing and the differencing with respect to preceding N cycles), and an outlier score are illustrated on a left side of the drawing. The raw data corresponding to the measured data with the appearing anomaly indications (described as anomalous in the drawing), the data that has undergone the preprocessing (the smoothing and the differencing with respect to preceding N cycles), and an outlier score are illustrated on a right side of the drawing. In FIG. 6, a threshold 201 refers to the normality determination threshold obtained through the first waveform analysis. FIG. 6 shows that the outlier score is within the threshold 201 when the measured data is normal and goes beyond the threshold 201 when the measured data has the appearing anomaly indications. The preprocessing according to the present embodiment prevents the influence of a base component of the raw data that changes, facilitating the detection of any substantial changes, and enables improved accuracy of anomaly indication detection based on comparison between the outlier score and the normality determination threshold. While FIG. 6 is the schematic diagram, analysis using similar actual data confirms that the accuracy of anomaly indication detection can be improved by comparing an outlier score with the normality determination threshold.

While the smoothing and the differencing with respect to preceding N cycles are both performed in the preprocessing in the described example of the present embodiment, no smoothing may be performed. Improved accuracy of anomaly indication detection is enabled in that case as well compared to when no differencing with respect to preceding N cycles is performed. The smoothing may be performed or does not have to be performed before the differencing with respect to preceding N cycles as long as the preprocessing unit 13 performs, as described above, the differencing with respect to preceding N cycles for the first waveform analysis unit 14 to perform waveform similarity analysis using difference values with respect to the preceding N cycles for generating, as learned data, normal waveforms and a normality determination threshold to be used for determining whether or not there is normality.

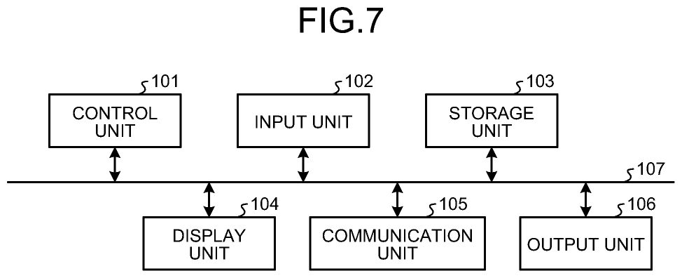

A description is provided next of a hardware configuration of the learning device 1 according to the present embodiment. For the learning device 1 of the present embodiment, a program is executed on a computer system as a computer program describing the operations of the learning device 1. Therefore, the computer system functions as the learning device 1. FIG. 7 is a diagram illustrating a configuration example of the computer system that implements the learning device 1 according to the present embodiment. As illustrated in FIG. 7, this computer system includes a control unit 101, an input unit 102, a storage unit 103, a display unit 104, a communication unit 105, and an output unit 106, all of which are connected via a system bus 107.

In FIG. 7, the control unit 101 is, for example, a processor such as a central processing unit (CPU) and executes the program describing the operations of the learning device 1 according to the present embodiment. The control unit 101 may be partly implemented with dedicated hardware such as a graphics processing unit (GPU) or a field-programmable gate array (FPGA). The input unit 102 includes, for example, a keyboard and a mouse, among others and is used by a user of the computer system for inputting various information. The storage unit 103 includes various types of memory, such as random-access memory (RAM) and read-only memory (ROM), and a storage device, such as a hard disk. The storage unit 103 stores the program to be executed by the control unit 101 and necessary data obtained during the operations, among others. Furthermore, the storage unit 103 is used as a temporary storage area for the program. The display unit 104 is a display, a liquid crystal display (LCD), or another device and displays various screens for the user of the computer system. The communication unit 105 is a transmitter and receiver that performs communication processing. The output unit 106 is a printer, a speaker, or another device. FIG. 7 provides the example, and the configuration of the computer system is not limited to the example of FIG. 7.

A description is provided here of an example of how the computer system operates until the program according to the present embodiment becomes executable. The computer program is installed in the storage unit 103 of the computer system with the above-described configuration from, for example, a compact disc (CD)-ROM or a Digital Versatile Disc (DVD)-ROM set in a CD-ROM or DVD-ROM drive that is not illustrated. When executed, the program read from the storage unit 103 is stored in a main storage area of the storage unit 103. In this state, the control unit 101 performs the operations as the learning device 1 of the present embodiment according to the program stored in the storage unit 103.

While the program describing the operations of the learning device 1 is provided on the CD-ROM or the DVD-ROM, which serves as a recording medium, in the above description, this is not limiting. Depending on the computer system configuration, program capacity to be provided, and others, the program to be used may be provided, for example, from a transmission medium such as the Internet via the communication unit 105.

The program according to the present embodiment causes, for example, the computer system that generates learned data to be used for anomaly indication detection to execute a step of subtracting, from a value at each of points in one cycle of normal data (data from the normal state), an average of values at corresponding points in normal data from one to N cycles ago in computing difference values with respect to the preceding N cycles; and a step of generating, through waveform similarity analysis using the difference values with respect to the preceding N cycles, normal waveforms and a normality determination threshold to be used for determining whether or not there is normality as the learned data.

The preprocessing unit 13, the first waveform analysis unit 14, and the to-be-removed waveform extraction unit 15 illustrated in FIG. 1 are implemented when the control unit 101 illustrated in FIG. 7 executes the computer program stored in the storage unit 103 illustrated in FIG. 7. For the implementation of the preprocessing unit 13, the first waveform analysis unit 14, and the to-be-removed waveform extraction unit 15 illustrated in FIG. 1, the storage unit 103 illustrated in FIG. 7 is also used. The data storage unit 12, the to-be-removed waveform storage unit 16, and the first learned data storage unit 17 illustrated in FIG. 1 are part of the storage unit 103 illustrated in FIG. 7. The data acquisition unit 11 illustrated in FIG. 1 is implemented with the communication unit 105 and the control unit 101 illustrated in FIG. 7. The learning device 1 may be implemented by a plurality of computer systems. For example, the learning device 1 may be implemented by a cloud computer system.

As with the learning device 1, the anomaly indication detection device 2 is also implemented by a computer system as in FIG. 7. The preprocessing unit 23, the first waveform analysis unit 24, and the overdetection elimination unit 25 illustrated in FIG. 1 are implemented when the control unit 101 illustrated in FIG. 7 executes a computer program stored in the storage unit 103 illustrated in FIG. 7. For the implementation of the preprocessing unit 23, the first waveform analysis unit 24, and the overdetection elimination unit 25 illustrated in FIG. 1, the storage unit 103 illustrated in FIG. 7 is also used. The data storage unit 22, the to-be-removed waveform storage unit 26, and the first learned data storage unit 27 illustrated in FIG. 1 are part of the storage unit 103 illustrated in FIG. 7. The data acquisition unit 21 illustrated in FIG. 1 is implemented with the communication unit 105 and the control unit 101 illustrated in FIG. 7. The detection result output unit 28 is implemented with the communication unit 105 or the display unit 104. In cases where the computer system that implements the anomaly indication detection device 2 is the above-mentioned slave station, this computer system may be simpler than the computer system illustrated in FIG. 7. For example, this computer system may be the computer system illustrated in FIG. 7 from which the display unit 104 and the output unit 106 are omitted.

As described above, the anomaly indication detection system 3 according to the present embodiment performs the anomaly indication detection through the waveform similarity analysis where the normal waveforms are learned, and performs the differencing with respect to preceding N cycles in the preprocessing during the learning. In this way, the improved accuracy of anomaly indication detection is enabled. Further performing the smoothing in the preprocessing allows for a further improvement in the accuracy of anomaly indication detection.

### Second Embodiment

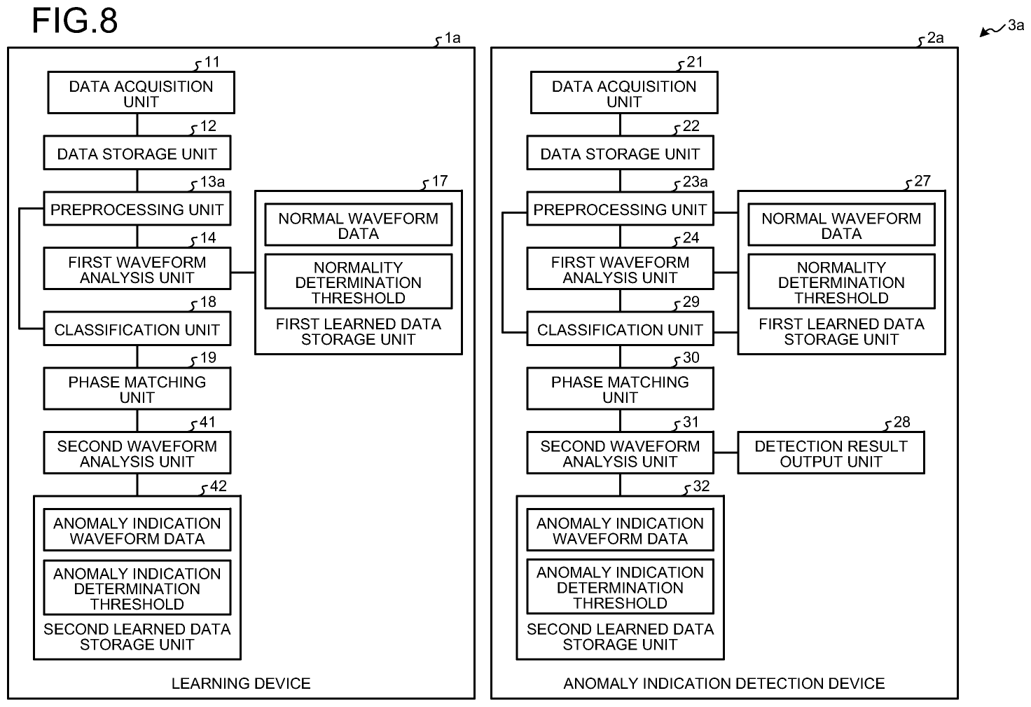

FIG. 8 is a diagram illustrating a configuration example of an anomaly indication detection system according to a second embodiment. The anomaly indication detection system 3a according to the present embodiment includes a learning device 1a and an anomaly indication detection device 2a. The learning device 1a according to the present embodiment includes a preprocessing unit 13a, a classification unit 18, a phase matching unit 19, a second waveform analysis unit 41, and a second learned data storage unit 42 instead of the preprocessing unit 13, the to-be-removed waveform extraction unit 15, and the to-be-removed waveform storage unit 16 and is otherwise similar to the learning device 1 according to the first embodiment. The anomaly indication detection device 2a according to the present embodiment includes a preprocessing unit 23a, a classification unit 29, a phase matching unit 30, a second waveform analysis unit 31, and a second learned data storage unit 32 instead of the preprocessing unit 23, the overdetection elimination unit 25, and the to-be-removed waveform storage unit 26 and is otherwise similar to the anomaly indication detection device 2 according to the first embodiment. Constituent elements with the same functions as those in the first embodiment have the same reference characters as in the first embodiment and are not described in order to omit redundancy. A description provided below is mainly of differences from the first embodiment.

As described in the first embodiment, the first waveform analysis unit 14 learns normal waveforms through the waveform similarity analysis. Further included in the present embodiment is the second waveform analysis unit 41 that performs waveform similarity analysis using data with anomaly indications, that is to say, anomaly indication data to generate data of anomaly indication waveforms and an anomaly indication determination threshold to be used for determining whether or not there is an anomaly indication. The anomaly indication waveforms and the anomaly indication determination threshold, too, are learned data to be used for anomaly indication detection. The anomaly indication waveforms are waveforms with appearing anomaly indications. In the present embodiment, when an anomaly indication is detected on the basis of a determination made by the first waveform analysis unit 24, anomaly indication detection using the anomaly indication waveforms as learned results is performed instead of the type-specific filtering that uses the determination condition determined by the to-be-removed waveform extraction unit 15. As in the first embodiment, a description is hereinafter provided of an example in which measured instantaneous value data of at least one of zero-phase current or zero-phase voltage being measured in a power distribution system is used as time-series data; however, the configuration and operations of the present embodiment are also applicable to other time-series data as in the first embodiment.

The operations of the present embodiment are described next. The operation during learning is described first. The learning device 1a according to the present embodiment also learns the normal waveforms through the waveform similarity analysis. In other words, the operations of steps S1 to S5 illustrated in FIG. 3 are performed. It is to be noted that the to-be-removed waveform extraction unit 15 and the to-be-removed waveform storage unit 16 described in the first embodiment may be provided in the present embodiment as well for step S6 to be performed.

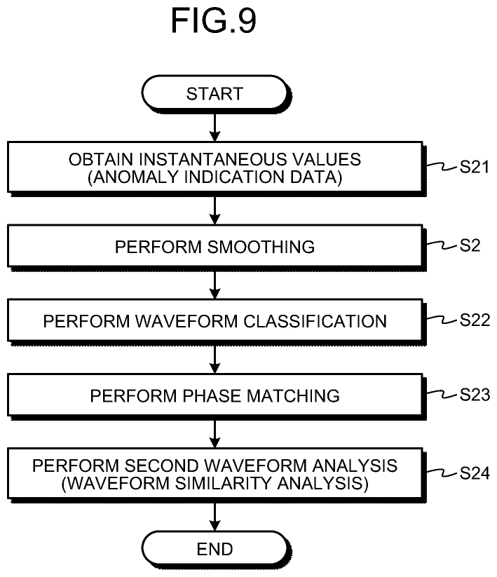

FIG. 9 is a flowchart illustrating an example of a procedure for learning waveforms with anomaly indications through the waveform similarity analysis according to the present embodiment. As illustrated in FIG. 9, the learning device 1a obtains instantaneous values (anomaly indication data) (step S21). Specifically, the data acquisition unit 11 obtains, for example, measured instantaneous value data of waveforms known to have anomaly indications as the anomaly indication data from another device not illustrated. The anomaly indication data to be input is data from a plurality of short intervals (e.g., unit intervals).

Next, the learning device 1a performs the smoothing as in the first embodiment (step S2), and the smoothed data is input to the classification unit 18. Next, the learning device 1a performs waveform classification (step S22). Specifically, the classification unit 18 classifies the smoothed data according to distance, and outputs the classified data to the phase matching unit 19. While the classification unit 18 may use any classification method, the classification unit 18 classifies, using a K-Shape method, for example. Since this waveform classification is intended to improve accuracy of anomaly indication waveforms by classifying those with lower similarities (increased distances), no waveform classification may be performed as long as higher-similarity waveforms can be detected.

Next, the learning device 1a performs phase matching (step S23). Specifically, the phase matching unit 19 performs the phase matching on the plural data inputs from the classification unit 18. For learning of normal waveforms, continuous time-series data of a normal period is typically input as input data; however, for learning of anomaly indication waveforms, that is to say, waveforms with anomaly indications, discontinuous data inputs from short intervals are typical. Therefore, the phase matching is performed to align phases among the plural data inputs within power supply cycles. The phase matching may be done by an operator who specifies an offset amount while checking each waveform or may be performed by another method. For phase-matched data inputs, the phase matching does not have to be performed. The phase matching and second waveform analysis may be performed for each group classified by the classification unit 18. In that case, the anomaly indication determination threshold may be set for each group.

Next, the learning device 1a performs the second waveform analysis (waveform similarity analysis) (step S24). Specifically, the second waveform analysis unit 41 uses the data inputs from the phase matching unit 19 to compute outlier scores and uses the computed outlier scores to determine an anomaly indication determination threshold to be used for determining whether or not there is an anomaly indication. While the data inputs are different, the waveform similarity analysis operation itself is similar to the operation of the first waveform analysis unit 14 of the first embodiment. The anomaly indication determination threshold is set to, for example, 3σ as in the first embodiment; however, this is not limiting. The second waveform analysis unit 41 stores the data of the anomaly indication waveforms and the anomaly indication determination threshold in the second learned data storage unit 42. The second learned data storage unit 32 of the anomaly indication detection device 2a stores the information stored in the second learned data storage unit 42 of the learning device 1a. The information of the second learned data storage unit 42 is reflected in the second learned data storage unit 32 in the same way as the information of the first learned data storage unit 17 is reflected in the first learned data storage unit 27 in the first embodiment.

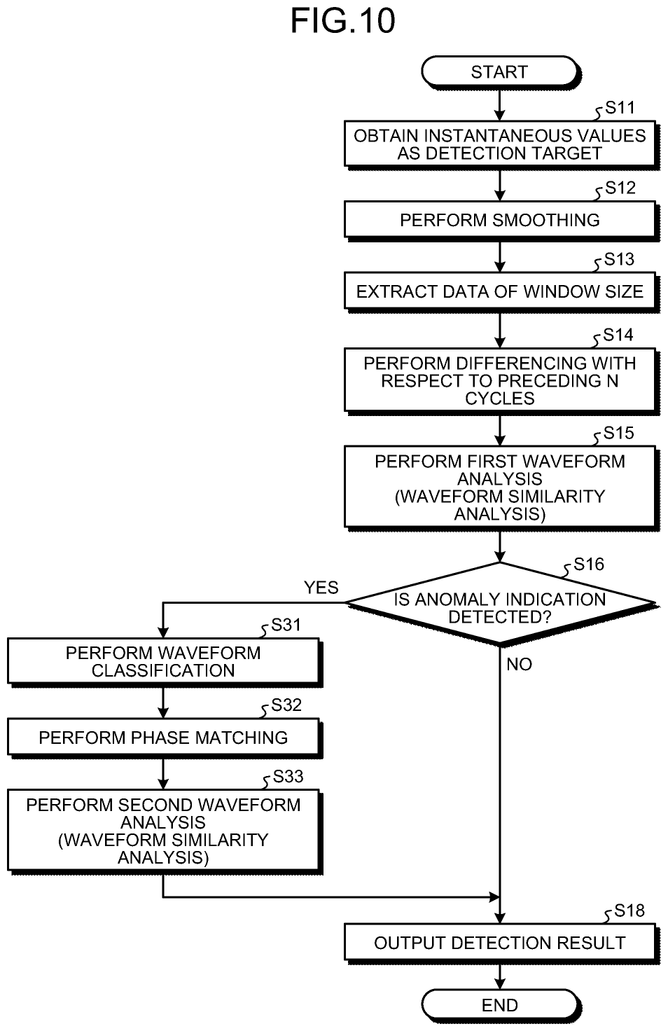

FIG. 10 is a flowchart illustrating an example of a procedure during inference by the anomaly indication detection device 2a according to the present embodiment. Steps S11 to S16 are identical to those of the first embodiment. However, the preprocessing unit 23a outputs data that has undergone the smoothing at step S12 (that is yet to undergo the differencing with respect to preceding N-cycles) to the classification unit 29. The first waveform analysis unit 24 outputs a result of determination to the classification unit 29. If the determination is Yes at step S16, the anomaly indication detection device 2a performs waveform classification (step S31). Specifically, the classification unit 29 classifies data as a detection target that has been determined to have an anomaly indication by the first waveform analysis unit 24 on the basis of distances between this data and data of anomaly indication waveforms of each group stored in the second learned data storage unit 32.

Next, the anomaly indication detection device 2a performs phase matching (step S32). Specifically, the phase matching unit 30 performs the operation of aligning phases of the data as the detection target with the anomaly indication waveform data of the corresponding group. Next, the anomaly indication detection device 2a performs second waveform analysis (waveform similarity analysis) (step S33). Specifically, the second waveform analysis unit 31 computes an outlier score, using the phase-matched data and the anomaly indication waveform data of corresponding group stored in the second learned data storage unit 32. The second waveform analysis unit 31 determines that an anomaly indication is present when the outlier score is within the anomaly indication determination threshold and determines that no anomaly indication is present when the outlier score is beyond the anomaly indication determination threshold. The second waveform analysis unit 31 outputs a determination result to the detection result output unit 28. Step S18 following step S33 is identical to that of the first embodiment. If the determination is No at step S16, the classification unit 29 outputs the determination result of the first waveform analysis unit 24 to the detection result output unit 28. In cases where as mentioned above, the operation described in step S6 of the first embodiment is performed during learning, the type-specific filtering is performed as in the first embodiment before step S31. When normality is determined as a result of the type-specific filtering, step S31 may be performed.

As described above, when the first waveform analysis unit 24 determines that the anomaly indication is present, the second waveform analysis unit 31 uses the detection target data, the anomaly indication waveforms, and the anomaly indication determination threshold to determine whether or not the anomaly indication is present. While the type-specific filtering is performed to eliminate the overdetection in the first embodiment, the second waveform analysis unit 31 performs the waveform similarity analysis using the anomaly indication waveforms as the learned results to eliminate the overdetection in the present embodiment. In the type-specific filtering, behavior of a device that operates only occasionally, for example, is specially stored, and what is detected from that behavior is determined to be normal and is removed. However, in the waveform similarity analysis by the second waveform analysis unit 31, only those similar to the past anomaly indication data are allowed to pass, while the others are eliminated. In other words, for a case where a specific waveform appears during an accident, the waveform similarity analysis by the second waveform analysis unit 31 allows waveforms similar to anomaly indication waveforms learned as waveforms with explanatory characteristics (well-known physical principles, presence of past records that have led to accidents, and others) to pass as anomaly indication waveforms. Therefore, the waveform similarity analysis by the second waveform analysis unit 31 enables a waveform detected to have an anomaly indication to be more explanatory than when the type-specific filtering is used.

In the above-described example, the second waveform analysis follows when the anomaly indication is detected in the first waveform analysis; however, the first waveform analysis and the second waveform analysis may be performed concurrently, and results of both the analyses may be used for anomaly indication detection. For example, a final detection result may indicate that an anomaly indication is present when the anomaly indication is detected in either the first waveform analysis or the second waveform analysis and indicate normality when the normality is determined in both the first waveform analysis and the second waveform analysis.

Excluding what has been described above, the operations of the present embodiment are similar to those of the first embodiment. For example, as with the learning device 1 of the first embodiment, the learning device 1a according to the present embodiment is also implemented by a computer system as in FIG. 7. The preprocessing unit 13a, the classification unit 18, the phase matching unit 19, and the second waveform analysis unit 41 illustrated in FIG. 8 are implemented when the control unit 101 illustrated in FIG. 7 executes a computer program stored in the storage unit 103 illustrated in FIG. 7. The second learned data storage unit 42 illustrated in FIG. 8 is part of the storage unit 103 illustrated in FIG. 7. The anomaly indication detection device 2a is also implemented, for example, by a computer system as in FIG. 7. The preprocessing unit 23a, the classification unit 29, the phase matching unit 30, and the second waveform analysis unit 31 illustrated in FIG. 8 are implemented when the control unit 101 illustrated in FIG. 7 executes a computer program stored in the storage unit 103 illustrated in FIG. 7. The second learned data storage unit 32 illustrated in FIG. 8 is part of the storage unit 103 illustrated in FIG. 7.

As in the first embodiment, in the present embodiment, the anomaly indication detection is performed through the waveform similarity analysis where the normal waveforms are learned, and the differencing with respect to preceding N cycles is performed in the preprocessing during learning. In this way, improved accuracy of anomaly indication detection is enabled.

### Third Embodiment

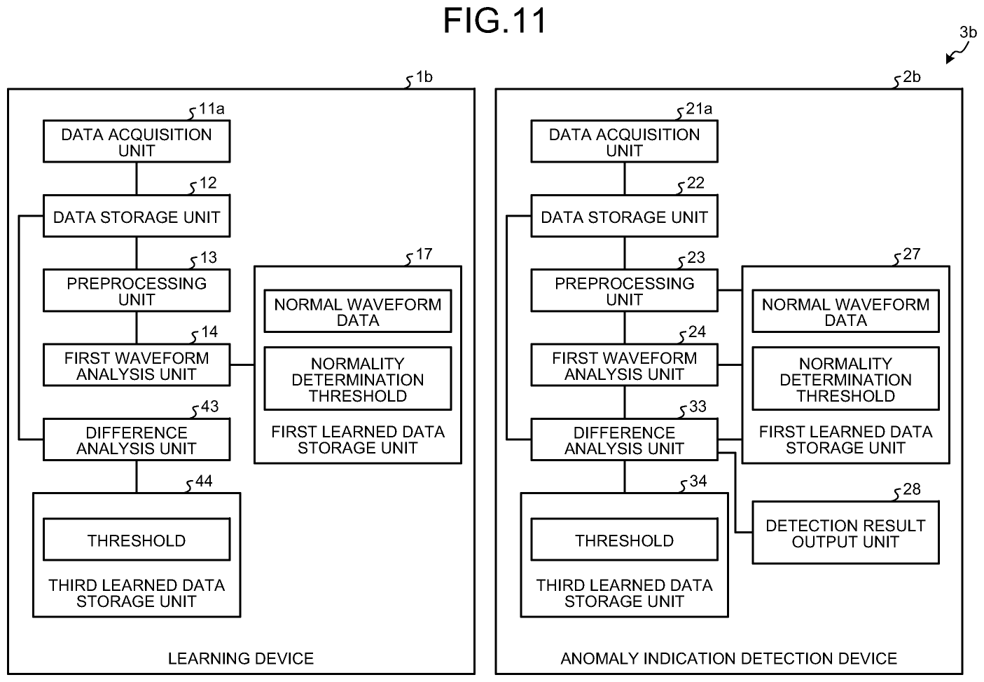

FIG. 11 is a diagram illustrating a configuration example of an anomaly indication detection system according to a third embodiment. The anomaly indication detection system 3b according to the present embodiment includes a learning device 1b and an anomaly indication detection device 2b. The learning device 1b according to the present embodiment includes a data acquisition unit 11a, a difference analysis unit 43, and a third learned data storage unit 44 instead of the data acquisition unit 11, the to-be-removed waveform extraction unit 15, and the to-be-removed waveform storage unit 16 and is otherwise similar to the learning device 1 according to the first embodiment. The anomaly indication detection device 2b according to the present embodiment includes a data acquisition unit 21a, a difference analysis unit 33, and a third learned data storage unit 34 instead of the data acquisition unit 21, the overdetection elimination unit 25, and the to-be-removed waveform storage unit 26 and is otherwise similar to the anomaly indication detection device 2 according to the first embodiment. Constituent elements with the same functions as those in the first embodiment have the same reference characters as in the first embodiment and are not described in order to omit redundancy. A description provided below is mainly of differences from the first embodiment.

As in the first embodiment, a description in the present embodiment is provided of an example in which measured instantaneous value data of at least one of zero-phase current or zero-phase voltage being measured as a measurement target in a power distribution system is used as time-series data. Furthermore, not only the measured instantaneous value data but also measured root-mean-square value data are obtained in the present embodiment. For example, in cases where a plurality of the anomaly indication detection devices 2b are used as slave stations that control the switches 4 as with the anomaly indication detection devices 2 of the first embodiment in FIG. 2, hardware processing capacity of each anomaly indication detection device 2b is conceivably constrained for reduced costs. When, for example, sampling is performed at 100 points per waveform, with power supply cycles being equivalent to 60 Hz in the power distribution system, the instantaneous values are data at 6000 points per second. Constant and real-time anomaly indication detection using such data causes a processing load to the anomaly indication detection device 2b, conceivably making its operations difficult if the hardware processing capacity is constrained. In the meantime, root-mean-square values are also generally obtained for each of the voltage and the current in the power distribution system as measured data. Since a root-mean-square value is one datum per cycle, the root-mean-square values are a small number compared with the instantaneous values.

Operations of the present embodiment are not limited to the case where the measured data as a detection target is of the at least one of the zero-phase current or the zero-phase voltage being measured in the power distribution system and are applicable if measured data as a detection target is of at least one of periodic current or periodic voltage, and cycles are not limited to a power supply frequency.

In the present embodiment, constant anomaly indication detection using root-mean-square values is performed. When an anomaly indication is detected through the anomaly indication detection using the root-mean-square values, anomaly indication detection using instantaneous values around the detected time is performed. In this way, the processing load on the anomaly indication detection device 2b can be reduced, and with detailed waveform analysis using the instantaneous values also performed, improved accuracy of anomaly indication detection is enabled.

A description is provided next of the operations of the present embodiment. The operation during learning is described first. The learning device 1b according to the present embodiment also learns normal waveforms through the waveform similarity analysis. In other words, the operations of steps S1 to S5 illustrated in FIG. 3 are performed. It is to be noted that the to-be-removed waveform extraction unit 15 and the to-be-removed waveform storage unit 16 described in the first embodiment may be provided in the present embodiment as well for step S6 to be performed.

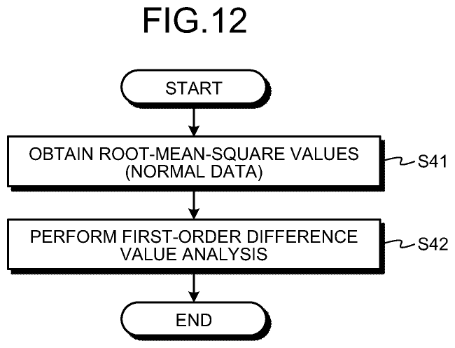

Furthermore, learning using root-mean-square values is performed in the present embodiment. FIG. 12 is a flowchart illustrating an example of a procedure for the learning using root-mean-square values according to the present embodiment. As FIG. 12 illustrates, the learning device 1b obtains root-mean-square values (normal data) (step S41). Specifically, the data acquisition unit 11a obtains and stores in the data storage unit 12 the measured root-mean-square value data of the measurement target, namely the measured root-mean-square value data of a normal period.

The learning device 1b performs first-order difference value analysis (step S42). Specifically, the difference analysis unit 43 computes a first-order difference value that is a difference between a measured root-mean-square value datum and a preceding datum. The difference analysis unit 43 then computes a standard deviation, using a plurality of the first-order difference values and using the standard deviation, determines a threshold to be used for determining whether or not there is normality. This threshold, too, is a learned datum to be used for anomaly indication detection. For example, the difference analysis unit 43 sets the threshold to 6G. While the threshold is 6σ here, the threshold is not limited to this value and may be determined, for example, on the basis of a result of a prior assessment. The difference analysis unit 43 stores the computed threshold in the third learned data storage unit 44. The third learned data storage unit 34 of the anomaly indication detection device 2b stores the information stored in the third learned data storage unit 44 of the learning device 1b. The information of the third learned data storage unit 44 is reflected in the third learned data storage unit 34 in the same way as the information of the first learned data storage unit 17 is reflected in the first learned data storage unit 27 in the first embodiment.

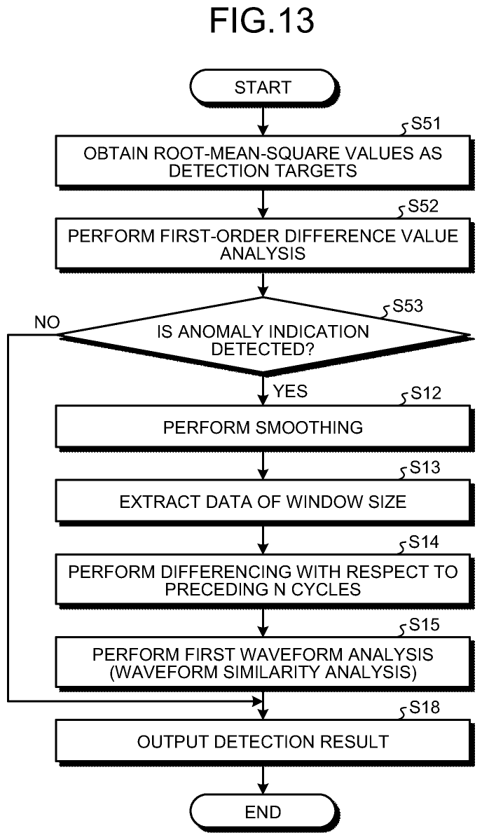

FIG. 13 is a flowchart illustrating an example of a procedure during inference by the anomaly indication detection device 2b according to the present embodiment. The anomaly indication detection device 2b obtains root-mean-square values as detection targets first (step S51). Specifically, the data acquisition unit 21a obtains and stores in the data storage unit 22 the root-mean-square values as the detection targets. At this time, the data acquisition unit 21a also obtains and stores in the data storage unit 22 instantaneous values.

Next, the anomaly indication detection device 2b performs first-order difference value analysis (step S52). Specifically, the difference analysis unit 33 computes a first-order difference value, using the root-mean-square values stored in the data storage unit 22 and compares the first-order difference value with the threshold stored in the third learned data storage unit 44.

If an anomaly indication is detected, that is to say, if the first-order difference value is beyond the threshold (Yes at step S53), steps S12 to S15 are performed as in the first embodiment. The first waveform analysis unit 24 notifies the detection result output unit 28 of a result of the determination made at step S15, and step S18 is performed. Specifically, instantaneous values obtained for a certain period, such as 2 seconds, after the detection of the anomaly indication are used for steps S12 to S15 to be performed. In cases where as mentioned above, the operation described in step S6 of the first embodiment is performed during learning, steps S16 and S17 may be performed as in the first embodiment after step S15.

If no anomaly indication is detected, that is to say, if there is normality (No at step S53), the operation of step S18 is performed. When the normality is determined, a detection result does not have to be output as in the first embodiment.

As described above, the difference analysis unit 33 in the present embodiment computes the first-order difference value between the measurement target's measured root-mean-square value data, which are the detection targets, and using the computed first-order difference value and the threshold, determines whether or not the anomaly indication is present. When the difference analysis unit 33 determines that the anomaly indication is present, the first waveform analysis unit 24 determines whether or not the anomaly indication is present through the waveform similarity analysis using difference values with respect to preceding N cycles, the normal waveforms, and a normality determination threshold.

In cases where the processing capacity of the anomaly indication detection device 2b is not constrained, the first waveform analysis and the first-order difference value analysis may be performed concurrently, and results of both the analyses may be used for anomaly indication detection. For example, a final detection result may indicate that an anomaly indication is present when the anomaly indication is detected in either the first waveform analysis or the first-order difference value analysis and indicate normality when the normality is determined in both the first waveform analysis and the first-order difference value analysis.

For example, as with the learning device 1 of the first embodiment, the learning device 1b according to the present embodiment is also implemented by a computer system as in FIG. 7. The difference analysis unit 43 illustrated in FIG. 11 is implemented when the control unit 101 illustrated in FIG. 7 executes a computer program stored in the storage unit 103 illustrated in FIG. 7. The third learned data storage unit 44 illustrated in FIG. 11 is part of the storage unit 103 illustrated in FIG. 7. The data acquisition unit 11a illustrated in FIG. 11 is implemented with the communication unit 105 and the control unit 101 illustrated in FIG. 7. The anomaly indication detection device 2b is also implemented, for example, by a computer system as in FIG. 7. The difference analysis unit 33 illustrated in FIG. 11 is implemented when the control unit 101 illustrated in FIG. 7 executes a computer program stored in the storage unit 103 illustrated in FIG. 7. The third learned data storage unit 34 illustrated in FIG. 11 is part of the storage unit 103 illustrated in FIG. 7. The data acquisition unit 21a illustrated in FIG. 11 is implemented with the communication unit 105 and the control unit 101 illustrated in FIG. 7.

As in the first embodiment, in the present embodiment, the anomaly indication detection is performed through the waveform similarity analysis where the normal waveforms are learned, and the differencing with respect to preceding N cycles is performed in the preprocessing during learning. In this way, improved accuracy of anomaly indication detection is enabled. Furthermore, there is the combination with the anomaly indication detection using root-mean-square values in the present embodiment. When a determination is made in the anomaly indication detection using the root-mean-square values that there is an anomaly indication, the anomaly indication detection using instantaneous values is performed, thus reducing the processing load on the anomaly indication detection device 2b compared to when the anomaly indication detection constantly using instantaneous values is performed.

### Fourth Embodiment

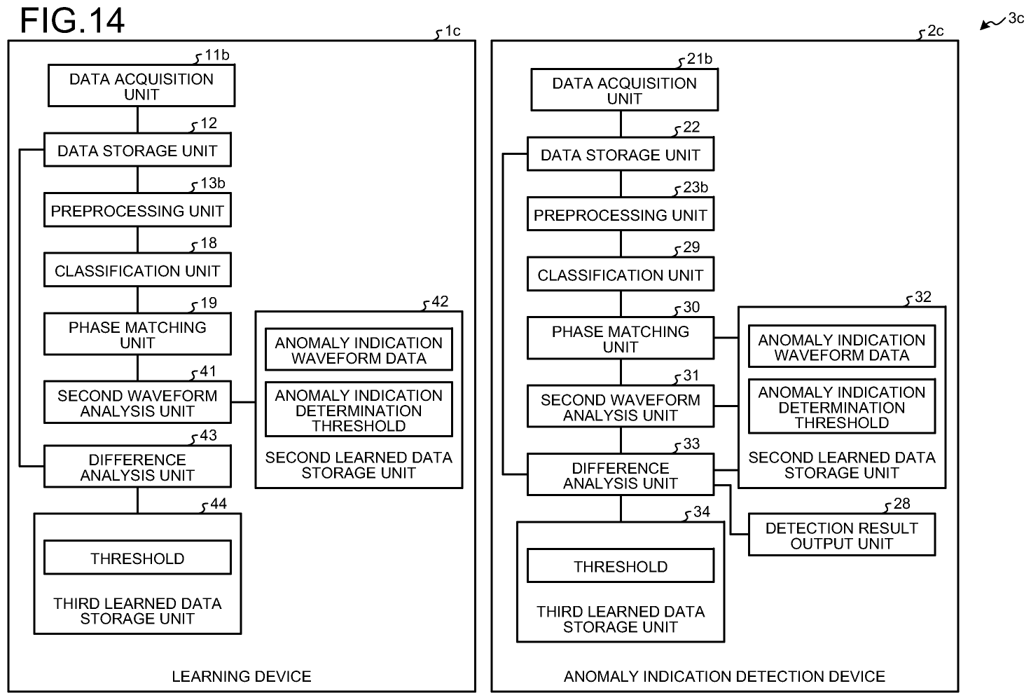

FIG. 14 is a diagram illustrating a configuration example of an anomaly indication detection system according to a fourth embodiment. The anomaly indication detection system 3c according to the present embodiment includes a learning device 1c and an anomaly indication detection device 2c. The learning device 1c according to the present embodiment includes a data acquisition unit 11b, a preprocessing unit 13b, the classification unit 18, the phase matching unit 19, the second waveform analysis unit 41, and the second learned data storage unit 42 instead of the data acquisition unit 11a, the preprocessing unit 13, the first waveform analysis unit 14, and the first learned data storage unit 17 of the third embodiment and is otherwise similar to the learning device 1b according to the third embodiment. The anomaly indication detection device 2c according to the present embodiment includes a data acquisition unit 21b, a preprocessing unit 23b, the classification unit 29, the phase matching unit 30, the second waveform analysis unit 31, and the second learned data storage unit 32 instead of the data acquisition unit 21a, the preprocessing unit 23, the first waveform analysis unit 24, and the first learned data storage unit 27 of the third embodiment and is otherwise similar to the anomaly indication detection device 2b according to the third embodiment.

The classification unit 18, the phase matching unit 19, the second waveform analysis unit 41, the second learned data storage unit 42, the classification unit 29, the phase matching unit 30, the second waveform analysis unit 31, and the second learned data storage unit 32 are identical respectively to the classification unit 18, the phase matching unit 19, the second waveform analysis unit 41, the second learned data storage unit 42, the classification unit 29, the phase matching unit 30, the second waveform analysis unit 31, and the second learned data storage unit 32 described in the second embodiment. Constituent elements with the same functions as those in the second and third embodiments have the same reference characters as in the second and third embodiments and are not described in order to omit redundancy. A description provided below is mainly of differences from the second and third embodiments.

The present embodiment combines the anomaly indication detection using root-mean-square values that has been described in the third embodiment and the anomaly indication detection using learned anomaly indication waveforms that has been described in the second embodiment. In the present embodiment, the preprocessing unit 13b does not perform the differencing with respect to preceding N cycles, but the smoothing as preprocessing and outputs preprocessed data to the second waveform analysis unit 41. Learning by the learning device 1c according to the present embodiment includes performing the second embodiment's operations illustrated in FIG. 9 and performing the third embodiment's operations illustrated in FIG. 12. In other words, the learning device 1c according to the present embodiment generates learned data by performing normal waveform learning using normal data (data from a normal state) and anomaly indication waveform learning using data with anomaly indications, that is to say, anomaly indication data. In the present embodiment, the normal waveform learning refers to the operation of the difference analysis unit 43, and the anomaly indication waveform learning refers to the operation of the second waveform analysis unit 41, which is an anomaly indication waveform analysis unit.

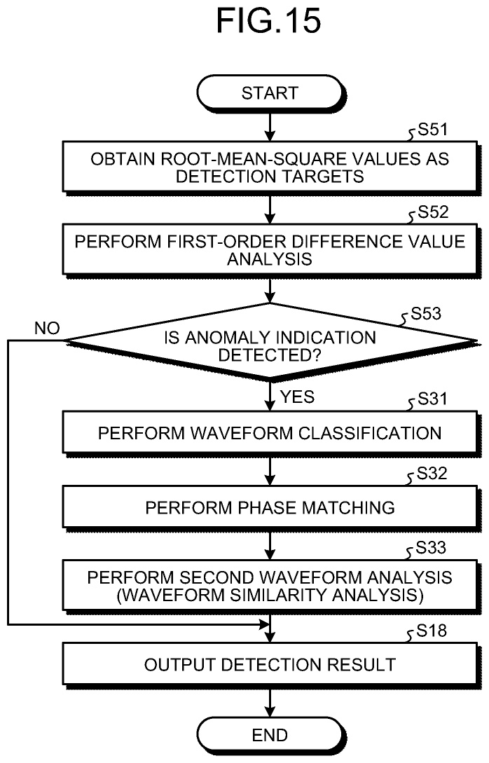

FIG. 15 is a flowchart illustrating an example of a procedure during inference by the anomaly indication detection device 2c according to the present embodiment. In the present embodiment, the preprocessing unit 23b does not perform the differencing with respect to preceding N cycles, but the smoothing as preprocessing and outputs preprocessed data to the second waveform analysis unit 31. Steps S51 to S53 are identical to those of the third embodiment. If Yes at step S53, steps S31 to S33, and step S18 are performed as in the second embodiment.

For example, as with the learning device 1 and the anomaly indication detection device 2 according to the first embodiment, the learning device 1c and the anomaly indication detection device 2c according to the present embodiment are also each implemented by a computer system as in FIG. 7.

As described above, in the present embodiment, normal waveforms are learned through the first-order difference value analysis, and anomaly indication waveforms are learned through the waveform similarity analysis. In other words, the normal waveform learning and the anomaly indication waveform learning are combined for anomaly indication detection. In this way, improved accuracy of anomaly indication detection is enabled.

### Fifth Embodiment

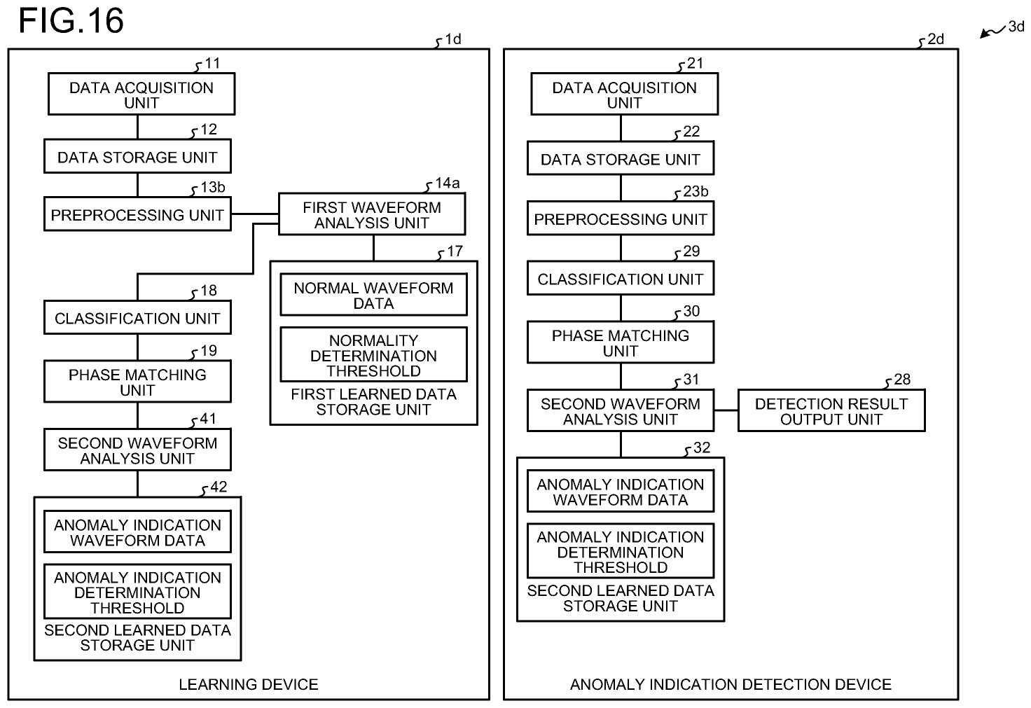

FIG. 16 is a diagram illustrating a configuration example of an anomaly indication detection system according to a fifth embodiment. The anomaly indication detection system 3d according to the present embodiment includes a learning device 1d and an anomaly indication detection device 2d. The learning device 1d according to the present embodiment includes the preprocessing unit 13b and a first waveform analysis unit 14a instead of the preprocessing unit 13a and the first waveform analysis unit 14 of the second embodiment and is otherwise similar to the learning device 1a according to the second embodiment. The anomaly indication detection device 2d according to the present embodiment includes the preprocessing unit 23b instead of the preprocessing unit 23a, eliminates the first waveform analysis unit 24 and the first learned data storage unit 27, and is otherwise similar to the anomaly indication detection device 2a according to the second embodiment. The preprocessing unit 13b and the preprocessing unit 23b are identical to those in the fourth embodiment. Constituent elements with the same functions as those in the second and fourth embodiments have the same reference characters as in the second and fourth embodiments and are not described in order to omit redundancy. A description provided below is mainly of differences from the second and fourth embodiments.

Learning is performed in the present embodiment for anomaly indication detection, using the waveform similarity analysis described in the second embodiment where anomaly indication waveforms are learned; however, a determination result of waveform similarity analysis of normal waveforms is used in anomaly indication waveform selection when anomaly indication waveforms are learned.

The first waveform analysis unit 14a according to the present embodiment has the functions of both the first waveform analysis unit 14 of the first embodiment and the first waveform analysis unit 24 of the first embodiment. As with the first waveform analysis unit 14 of the first embodiment, the first waveform analysis unit 14a performs the first waveform analysis using normal data stored in the data storage unit 12 to store data of normal waveforms and a normality determination threshold in the first learned data storage unit 17. Using a result of this learning, the waveform similarity analysis is performed where anomaly indication waveforms are learned.

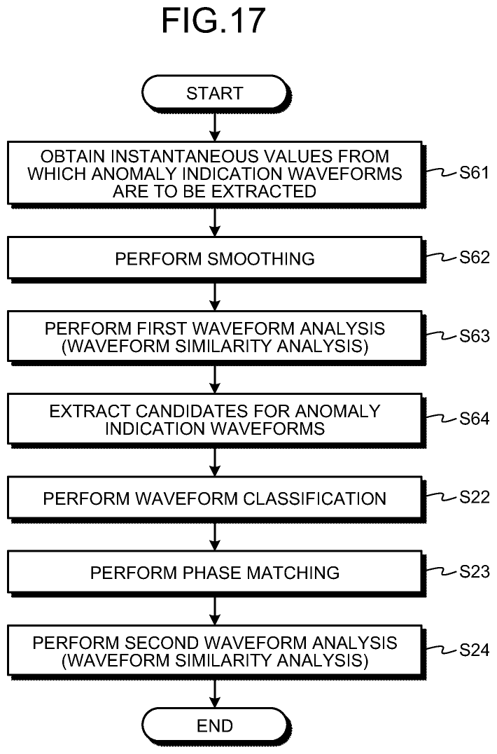

FIG. 17 is a flowchart illustrating an example of a procedure for the waveform similarity analysis where waveforms with anomaly indications are learned according to the present embodiment. As FIG. 17 illustrates, the learning device 1d obtains instantaneous values from which anomaly indication waveforms are to be extracted (step S61). Specifically, the data acquisition unit 11 obtains the measured instantaneous value data from which the anomaly indication waveforms are to be extracted and stores the measured data in the data storage unit 12. While the measured data is measured data from a period assumed to include the anomaly indication waveforms, any measured data may be input in cases where there is no known period assumed to include the anomaly indication waveforms.

Next, the learning device 1d performs the smoothing (step S62). Specifically, the preprocessing unit 13b performs the smoothing on the measured data stored in the data storage unit 12 and outputs the processed data to the first waveform analysis unit 14a.

Next, the learning device 1d performs the first waveform analysis (waveform similarity analysis) (step S63). Specifically, the first waveform analysis unit 14a segments the smoothed measured data to obtain data of unit intervals and compares a distance between data of each of the unit intervals and data of each of the normal waveforms stored in the first learned data storage unit 17 with the normality determination threshold stored in the first learned data storage unit 17, thus determining whether or not an anomaly indication is present in the unit interval data.

Next, the learning device 1d extracts candidates for the anomaly indication waveforms (step S64). Specifically, the first waveform analysis unit 14a extracts and outputs to the classification unit 18 data of unit intervals that have been determined to have the anomaly indications as the candidates for the anomaly indication waveforms. Subsequently, steps S22 to S24 are performed as in the second embodiment.

The anomaly indication detection device 2d according to the present embodiment performs step S12, steps S31 to S33, and step S18 that have been described in the second embodiment. As described above, the first waveform analysis unit 14a generates the normal waveforms and the normality determination threshold, which is used for the determination of normality, as the normal learned data through the waveform similarity analysis using the normal data, which is the data from a normal state. Using the detection target data, which is the data including the anomaly indication waveforms, and the normal learned data, the first waveform analysis unit 14a extracts the candidates for the data with anomaly indications as candidate data from the detection target data. Subsequently, using the candidate data, the second waveform analysis unit 41 performs the waveform similarity analysis to generate the anomaly indication waveforms and an anomaly indication determination threshold to be used for determining whether or not there is an anomaly indication as learned data. The learning device 1d according to the present embodiment performs normal waveform learning using the normal data, which is the data from the normal state, and anomaly indication waveform learning using the data with the anomaly indications, namely the anomaly indication data thus to generate the learned data. The normal waveform learning refers to the operation of the first waveform analysis unit 14a, which is a normal waveform analysis unit, and the anomaly indication waveform learning refers to the operation of the second waveform analysis unit 41, which is the anomaly indication waveform analysis unit.

For example, as with the learning device 1 and the anomaly indication detection device 2 according to the first embodiment, the learning device 1d and the anomaly indication detection device 2d according to the present embodiment are also each implemented by a computer system as in FIG. 7.

As described above, in the present embodiment, the result of the anomaly indication detection using the normal waveforms in the waveform similarity analysis is used for determining the candidates for the anomaly indication waveforms, and the anomaly indication waveforms are learned through the waveform similarity analysis using the determined candidates. As described, the present embodiment, too, combines the normal waveform learning and the anomaly indication waveform learning. In this way, improved accuracy of anomaly indication detection is enabled.

The above configurations illustrated in the embodiments are illustrative, can be combined with other techniques that are publicly known, and can be partly omitted or changed without departing from the gist. The embodiments can be combined with each other.

### REFERENCE SIGNS LIST

1, 1a, 1b, 1c, 1d learning device; 2, 2a, 2b, 2c, 2d anomaly indication detection device; 3, 3a, 3b, 3c, 3d anomaly indication detection system; 4 switch; 11, 11a, 11b, 21, 21a, 21b data acquisition unit; 12, 22 data storage unit; 13, 13a, 13b, 23, 23a, 23b preprocessing unit; 14, 14a, 24 first waveform analysis unit; 15 to-be-removed waveform extraction unit; 16, 26 to-be-removed waveform storage unit; 17, 27 first learned data storage unit; 18, 29 classification unit; 19 phase matching unit; 25 overdetection elimination unit; 28 detection result output unit; 31, 41 second waveform analysis unit; 32, 42 second learned data storage unit; 33, 43 difference analysis unit; 34, 44 third learned data storage unit.

1. A learner to generate learned data to be used for anomaly indication detection, the learner comprising:
a preprocessing circuitry to subtract, from a value at each of points in one cycle of normal data, an average of values at corresponding points in the normal data from one to N cycles ago in computing difference values with respect to the preceding N cycles, the one cycle corresponding to a specified time length, N being an integer greater than or equal to 2, the normal data being data from a normal state; and
a first waveform analysis circuitry to generate, through waveform similarity analysis using the difference values with respect to the preceding N cycles, normal waveforms and a normality determination threshold to be used in determining whether or not there is normality as the learned data.

2. The learner according to claim 1, wherein the preprocessing circuitry performs smoothing using a first-order lag filter on the normal data and computes the difference values with respect to the preceding N cycles, using the normal data smoothed.

3. The learner according to claim 1, comprising:
a second waveform analysis circuitry to generate, as additions to the learned data, anomaly indication waveforms and an anomaly indication determination threshold to be used in determining whether or not there is an anomaly indication through waveform similarity analysis using anomaly indication data, the anomaly indication data being data with anomaly indications.

4. The learner according to claim 1, wherein
the normal data is measured instantaneous value data of at least one of voltage or current as a measurement target, and
the learner comprises a difference analysis circuitry to compute first-order difference values for normal measured root-mean-square value data of the measurement target and generate, as an addition to the learning data, a threshold to be used in determining whether or not there is normality, using first-order difference values computed.

5. A learner to generate learned data to be used for anomaly indication detection, wherein
the learner performs normal waveform learning using normal data and anomaly indication waveform learning using anomaly indication data in generating the learned data, the normal data being data from a normal state, the anomaly indication data being data with anomaly indications.

6. The learner according to claim 5, comprising:
a difference analysis circuitry to perform the normal waveform learning; and
an anomaly indication waveform analysis circuitry to perform the anomaly indication waveform learning, wherein
the difference analysis circuitry computes first-order difference values for measured root-mean-square value data of at least one of voltage or current as a measurement target and using first-order difference values computed, generates a threshold that is to be used in determination of normality and included in the learned data, and
the anomaly indication waveform analysis circuitry generates, for inclusion in the learned data, anomaly indication waveforms and an anomaly indication determination threshold to be used in determining whether or not there is an anomaly indication through waveform similarity analysis using anomaly indication data of the measurement target, the anomaly indication data being measured instantaneous value data with anomaly indications.

7. The learner according to claim 5, comprising:
a normal waveform analysis circuitry to perform the normal waveform learning; and
an anomaly indication waveform analysis circuitry to perform the anomaly indication waveform learning, wherein
the normal waveform analysis circuitry generates normal waveforms and a normality determination threshold to be used in determination of normality as normal learned data through waveform similarity analysis using normal data and using detection target data and the normal learned data, extracts candidates for data with anomaly indications as candidate data from the detection target data, the normal data being data from a normal state, the detection target data being data including anomaly indication waveforms, and
the anomaly indication waveform analysis circuitry generates, for inclusion in the learned data, anomaly indication waveforms and an anomaly indication determination threshold to be used in determining whether or not there is an anomaly indication through waveform similarity analysis using the candidate data.

8. The learner according to any one of claims 1 to 7, wherein the anomaly indication detection using the learned data is performed on measured data of at least one of zero-phase voltage or zero-phase current of a power distribution system that is measured at a slave station that controls a switcher sectionalizing the power distribution system.

9. An anomaly indication detector to perform anomaly indication detection using learned data, the anomaly indication detector comprising:
a preprocessing circuitry to subtract, from a value at each of points in one cycle of detection target data, an average of values at corresponding points in the detection target data from one to N cycles ago in computing difference values with respect to the preceding N cycles, the one cycle corresponding to a specified time length, N being an integer greater than or equal to 2, the detection target data being data as an anomaly indication detection target; and
a first waveform analysis circuitry to determine whether or not there is an anomaly indication through waveform similarity analysis using the difference values with respect to the preceding N cycles and the learned data, wherein
the learned data includes normal waveforms and a normality determination threshold that have been generated through waveform similarity analysis using difference values with respect to preceding N cycles based on normal data that is data from a normal state, the normality determination threshold being used in determination of normality.

10. The anomaly indication detector according to claim 9, comprising
a second waveform analysis circuitry, wherein
the learned data includes anomaly indication waveforms and an anomaly indication determination threshold that have been generated through waveform similarity analysis using anomaly indication data, the anomaly indication determination threshold being used in determining whether or not there is an anomaly indication, the anomaly indication data being data with anomaly indications, and
when the first waveform analysis circuitry determines that an anomaly indication is present, the second waveform analysis circuitry determines whether or not an anomaly indication is present, using the detection target data, the anomaly indication waveforms, and the anomaly indication determination threshold.

11. The anomaly indication detector according to claim 9, comprising
a difference analysis circuitry, wherein
the normal data is measured instantaneous value data of at least one of voltage or current as a measurement target,
the learned data includes a threshold computed using first-order difference values for normal measured root-mean-square value data of the measurement target, the threshold being used in determining whether or not there is normality,
the difference analysis circuitry computes a first-order difference value between measured root-mean-square value data of the measurement target that are detection targets and using a first-order difference value computed and the threshold, determines whether or not an anomaly indication is present, and
when the difference analysis circuitry determines that an anomaly indication is present, the first waveform analysis circuitry determines whether or not an anomaly indication is present through waveform similarity analysis using the difference values with respect to the preceding N cycles, the normal waveforms, and the normality determination threshold.

12. An anomaly indication device detector to perform anomaly indication detection using learned data, the anomaly indication detector comprising:
a difference analysis circuitry to compute a first-order difference value between measured root-mean-square value data of at least one of voltage or current as a measurement target and determine whether or not there is an anomaly indication, using a first-order difference value computed and a threshold; and
an anomaly indication waveform analysis circuitry to determine whether or not an anomaly indication is present, using measured instantaneous value data of the measurement target, anomaly indication waveforms, and an anomaly indication determination threshold when the difference analysis circuitry determines that an anomaly indication is present, wherein
the threshold is the learned data computed using first-order difference values for normal measured root-mean-square value data of the measurement target, and
the anomaly indication waveforms and the anomaly indication determination threshold are included in the learned data and have been generated through waveform similarity analysis using anomaly indication data of the measurement target, the anomaly indication data being measured instantaneous value data with anomaly indications.

13. The anomaly indication detector according to any one of claims 9 to 12, wherein the anomaly indication detector is a slave station to control a switcher sectionalizing a power distribution system and performs the anomaly indication detection using the learned data on measured data of at least one of zero-phase voltage or zero-phase current of the power distribution system.

14. An anomaly indication detection system comprising:
a learner to generate learned data to be used for anomaly indication detection; and
an anomaly indication detector to perform anomaly indication detection using the learned data, wherein
the learner includes
a preprocessing circuitry to subtract, from a value at each of points in one cycle of normal data, an average of values at corresponding points in the normal data from one to N cycles ago in computing difference values with respect to the preceding N cycles, the one cycle corresponding to a specified time length, N being an integer greater than or equal to 2, the normal data being data from a normal state and
a first waveform analysis circuitry to generate, through waveform similarity analysis using the difference values with respect to the preceding N cycles, normal waveforms and a normality determination threshold to be used in determining whether or not there is normality as the learned data, and
the anomaly indication detector includes
a preprocessing circuitry to subtract, from a value at each of points in one cycle of detection target data, an average of values at corresponding points in the detection target data from one to N cycles ago in computing difference values with respect to the preceding N cycles, the detection target data being data as an anomaly indication detection target and
a first waveform analysis circuitry to determine whether or not there is an anomaly indication through waveform similarity analysis using the difference values with respect to the preceding N cycles computed by the preprocessing circuitry of the anomaly indication detector and the learned data.

15. An anomaly indication detection system comprising:
a learner to generate learned data to be used for anomaly indication detection; and
an anomaly indication detector to perform anomaly indication detection using the learned data, wherein
the learner performs normal waveform learning using normal data and anomaly indication waveform learning using anomaly indication data in generating the learned data, the normal data being data from a normal state, the anomaly indication data being data with anomaly indications.

16. A learning method for a learner to generate learned data to be used for anomaly indication detection, the learning method comprising:
subtracting, by the learner, from a value at each of points in one cycle of normal data, an average of values at corresponding points in the normal data from one to N cycles ago in computing difference values with respect to the preceding N cycles, the one cycle corresponding to a specified time length, N being an integer greater than or equal to 2, the normal data being data from a normal state; and
generating, by the learner, through waveform similarity analysis using the difference values with respect to the preceding N cycles, normal waveforms and a normality determination threshold to be used in determining whether or not there is normality as the learned data.

17. A learning method for a learner to generate learned data to be used for anomaly indication detection, the learning method comprising:
performing, by the learner, normal waveform learning using normal data, the normal data being data from a normal state; and
performing, by the learner, anomaly indication waveform learning using anomaly indication data, the anomaly indication data being data with anomaly indications, wherein
the learned data is generated through the normal waveform learning and the anomaly indication waveform learning.

18. A non-transitory computer-readable storage medium having a program stored therein, the program to cause a computer system that generates learned data to be used for anomaly indication detection to execute:
subtracting, from a value at each of points in one cycle of normal data, an average of values at corresponding points in the normal data from one to N cycles ago in computing difference values with respect to the preceding N cycles, the one cycle corresponding to a specified time length, N being an integer greater than or equal to 2, the normal data being data from a normal state; and
generating, through waveform similarity analysis using the difference values with respect to the preceding N cycles, normal waveforms and a normality determination threshold to be used in determining whether or not there is normality as the learned data.

19. A non-transitory computer-readable storage medium having a program stored therein, the program to cause a computer system that generates learned data to be used for anomaly indication detection to execute:
performing normal waveform learning using normal data, the normal data being data from a normal state; and
performing anomaly indication waveform learning using anomaly indication data, the anomaly indication data being data with anomaly indications, wherein
the learned data is generated through the normal waveform learning and the anomaly indication waveform learning.
